(19) United States
(12) Patent Application Publication
(10) Pub. No.: US 2002/0179997 A1
(43) Pub. Date: Dec. 5, 2002

(54) Self-aligned corner Vt enhancement with isolation channel stop by ion implantation

(75) Inventors: George R. Goth, Poughkeepsie, NY (US); John Kim, Wappingers Falls, NY (US); Victor R. Nastasi, Hopewell Junction, NY (US)

Correspondence Address: WHITHAM, CURTIS & CHRISTOFFERSON, P.C., 11491 SUNSET HILLS ROAD, SUITE 340, RESTON, VA, 20190, US

(73) Assignee: International Business Machines Corporation, Armonk, NY (US)

(21) Appl. No.: 09/874,121

(22) Filed: Jun. 5, 2001

(51) Int. Cl. H01L 21/76

(52) U.S. Cl. 257/514; 438/433

(57) ABSTRACT

A process of fabricating a field effect transistor (FET) device uses the simultaneous implantation of the well species at the edge of the device and at the bottom of the shallow trench isolation (STI). This not only simplifies the process by defining the region for implantation at the device edge and at the bottom of the isolation with a single photo masking level, it also avoids the dual problems of corner Vt degradation and leakage across the bottom of the isolation trench. By implantation of the well species into the corner of the device region, the degradation of the corner Vt is mitigated by the additional channel doping in the edge of the device. The leakage across the bottom of the STI is eliminated by the simultaneous implantation of the well species at the interface thus raising the dopant level of the parasitic channel.

### BACKGROUND OF THE INVENTION

1. Field of the Invention

The present invention generally relates to the fabrication of field effect transistor (FET) devices and, more particularly, to a process which avoids the dual problems of corner threshold voltage (Vt) degradation and leakage across the bottom of the isolation trench while at the same time realizing certain economies by simplifying the manufacturing process.

2. Background Description

The corner threshold voltage (Vt) of FET devices is degraded by several process related issues such as the corner rounding of the silicon at the edge of the device, wrap-around of the gate conductor, and the thinning of the gate oxide. The resultant lowering of the corner Vt contributes to sub-Vt leakage and an overall degradation of chip yield and performance. Corner Vt degradation has been addressed by engineering the radius of curvature of the silicon at the edge of the device; however, this has produced only modest recovery of Vt. Corner Vt degradation has been mitigated by the introduction of oxidation catalysts like potassium, but such mobile ions are difficult to contain and contribute unwanted device leakage. Corner Vt degradation has also been minimized by divot fill process that minimizes gate conductor wrap-around, but this adds significant cost and process complexity.

A second problem encountered is the leakage across the bottom of the isolation trench caused by insufficient doping of the well at the isolation/silicon interface. Leakage across the bottom of the isolation is addressed by device well engineering. This is normally performed after the isolation is filled and planarized. As a result, controlling the peak concentration of the well at the bottom of the shallow trench isolation (STI) is more difficult and significant modifications of the dopant profile of the wells usually incurrs an increase in junction leakage for the source/drain diffusions of the FET.

### SUMMARY OF THE INVENTION

It is therefore an object of the present invention to provide a method of fabricating an FET device that avoids the problems of corner Vt degradation and leakage across the bottom of the isolation trench.

It is another object of the invention to provide a method of fabricating an FET device which defines the region for implantation at the device edge and the bottom of the isolation with a single photo masking level.

According to the invention, there is provided a process that addresses both problems by the simultaneous implantation of the well species at the edge of the device and at the bottom of the shallow trench isolation (STI). The invention is a method of defining the region for implantation at the device edge and at the bottom of the isolation with a single photo masking level.

By implantation of the well species into the corner of the device region, the degradation of the corner Vt is mitigated by the additional channel doping in the edge of the device. The leakage across the bottom of the STI is eliminated by the simultaneous implantation of the well species at the interface thus raising the dopant level of the parasitic channel.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a cross-sectional view of an FET device after STI is defined and surface films are pulled back by wet chemical etch;

FIG. 2 is a cross-sectional view of the device after a silicon dioxide layer is grown in the STI and exposed edge of the device region;

FIG. 3 is a cross-sectional view of the device showing the process of a boron implant; and

FIG. 4 is a cross-sectional view of the device after the isolation trench is filled and planarized and a gate conductor is applied.

### DETAILED DESCRIPTION OF A PREFERRED EMBODIMENT OF THE INVENTION

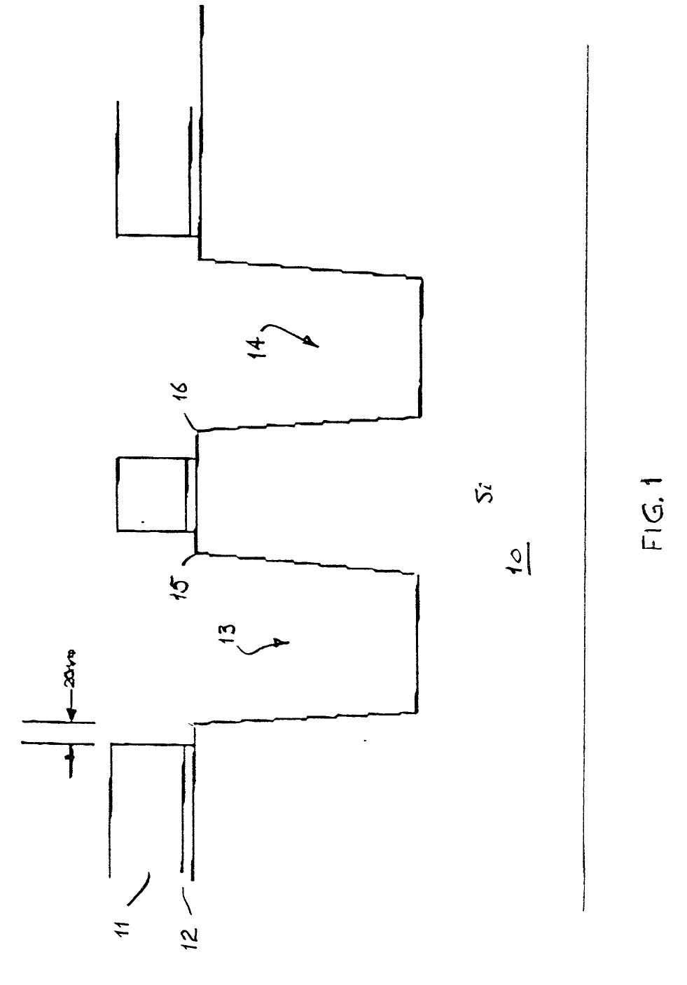

Referring now to the drawings, and more particularly to FIG. 1, there is shown in cross-sectional view the first step in the manufacture of an FET device according to the invention. A silicon substrate 10 is prepared by first depositing a layer of silicon dioxide 11 and then a layer of silicon nitride 12. Trenches 13 and 14 are formed in silicon substrate 10 by using a photolithiographic process to define the trenches in a photoresist applied to the silicon nitride layer 12 and then etching the trenches through the exposed silicon nitride and silicon dioxide layers into the silicon substrate as is conventional in the art. These trenches will be used to provide STI for the FET device. Next, the photoresist used to define the trenches 13 and 14 is removed, and the silicon nitride and silicon dioxide layers 12 and 11 are pulled back on the wafer surface to leave exposed edges 15 and 16. In the example shown, 120 nm of silicon nitride and 5 nm of silicon dioxide are simultaneously etched with hydrofluoric acid/glycerol to expose the edge of the device region by 20 nm.

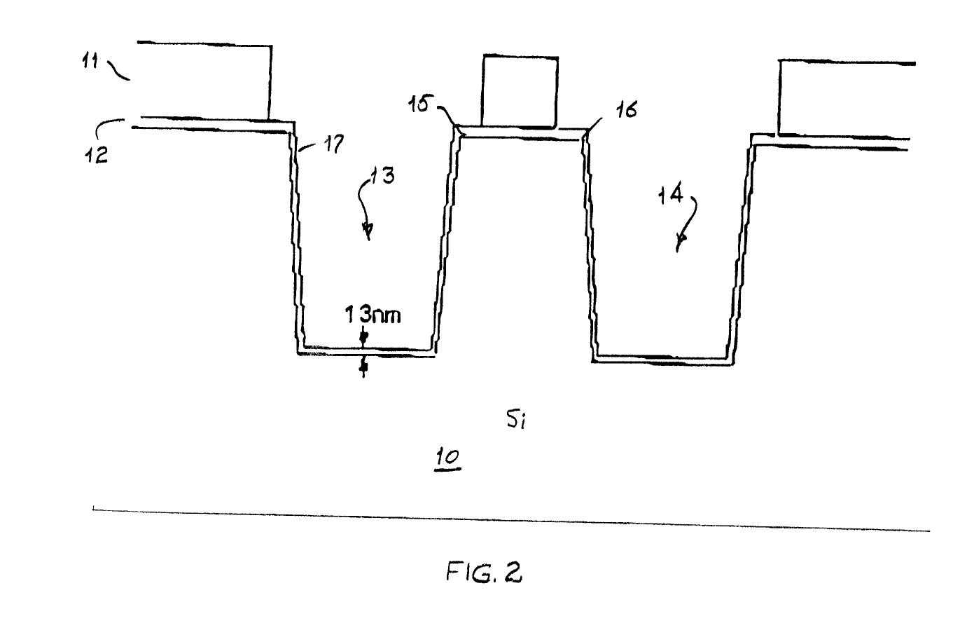

In the next step shown in FIG. 2, a silicon dioxide layer 17 is grown in the STI trenches 13 and 14 and the exposed edges 15 and 16 of the device region to provide sufficient passivation of the silicon surface and to serve as a screen oxide for the implant of the well species. In the example shown, a 13 nm oxide is grown on the exposed silicon surfaces.

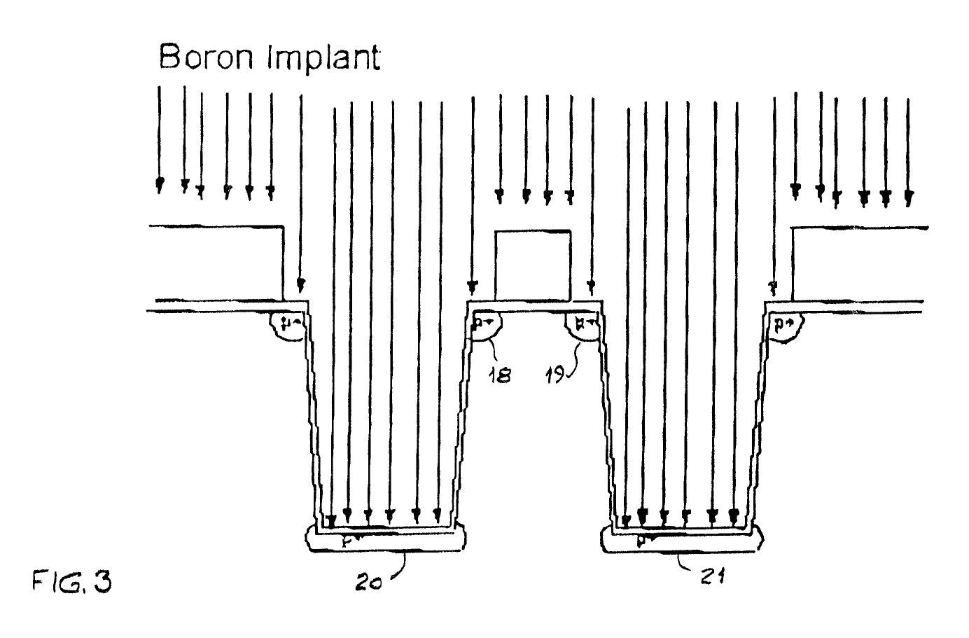

In FIG. 3, an implant of the same species as the well of the FET device is performed perpendicular to the silicon surface. The implant is performed at sufficient energy to place the peak concentration just below the interface of the oxide layer and silicon. The corner implantation at 18 and 19 will serve for carrier Vt control of the completed FET device, and the bottom implantation 20 and 21 at the bases of the trenches 13 and 14 will serve to prevent leakage across the bottom of the STI. In the example illustrated, a boron implant is performed in an n-type FET (NFET) device region at a dose range of 5E12 to 5E13 cm⁻² and an energy of 5 KeV. By implantation of the well species into the corners 18 and 19 of the device region, the degradation of the corner Vt is mitigated by the additional channel doping in the edge of the device. The leakage across the bottom of the STI is eliminated by the simultaneous implantation of the well species 20 and 21 at the interface thus raising the dopant level of the parasitic channel.

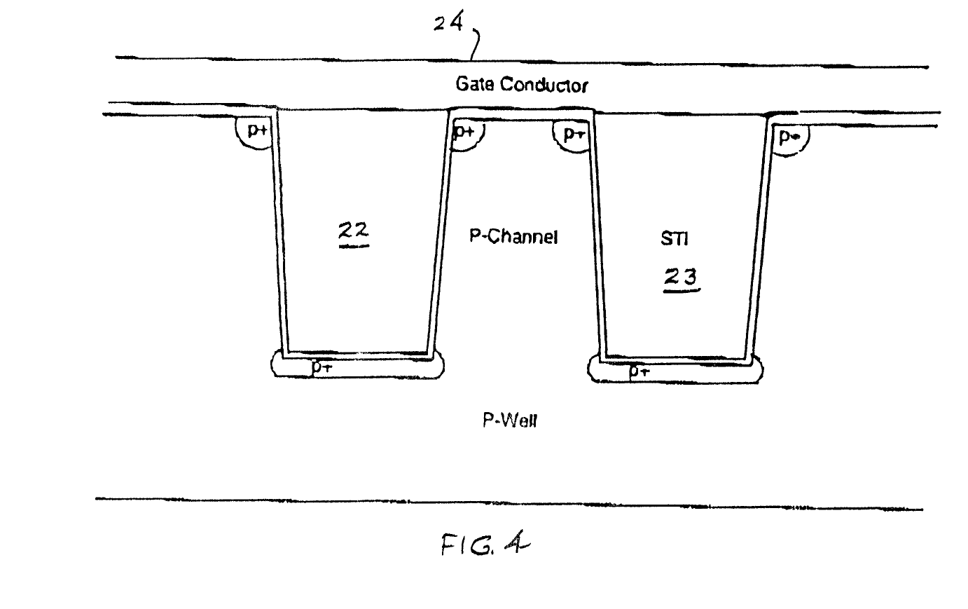

In FIG. 4, the isolation trenches 13 and 14 are filled with oxide 22 and 23, and the device is planarized using chemical-mechanical planarizing (CMP) or other conventional techniques, removing the silicon nitride layer. The device fabrication proceeds with the formation of the well, gate oxidation, and definition of the gate conductor 24.

While the invention has been described in terms of a single preferred embodiment, those skilled in the art will recognize that the invention can be practiced with modification within the spirit and scope of the appended claims.

Having thus described my invention, what I claim as new and desire to secure by letters patent is as follows:

1. A process of fabricating a field effect transistor (FET) device comprising the step of simultaneous implantation of a well species at edges of the device and at bottoms of shallow trench isolation (STI) of the FET device.

2. The process of fabricating an FET device as recited in claim 1, wherein the implantation is performed on a substrate in which trenches have been formed for the STI and surface layers are pulled back a finite amount to expose edges of the device.

3. The process of fabricating an FET device as recited in claim 2, further comprising the step of growing an oxide layer over the exposed substrate within the trenches and the exposed edges to provide a passivation layer prior to implantation.

4. The process of fabricating an FET device as recited in claim 2, wherein the surface layers are silicon dioxide and silicon nitride over a substrate of silicon.

5. The process of fabricating an FET device as recited in claim 4, further comprising the step of etching the silicon dioxide and silicon nitride layers after forming the trenches to expose edges of the device.

6. The process of fabricating an FET device as recited in claim 5, further comprising the step of growing an oxide layer over the exposed substrate within the trenches and the exposed edges to provide a passivation layer prior to implantation.

7. A field effect transistor (FET) device comprising implantation of a well species at edges of the device and at bottoms of shallow trench isolation (STI) of the FET device, the implantation at the edges of the device degradation of corner threshold voltage (Vt) of the device and leakage across the bottom of the STI being eliminated by the implantation at the bottoms of the STI.
